(19) United States
(12) Patent Application Publication
(10) Pub. No.: US 2006/0279309 A1
(43) Pub. Date: Dec. 14, 2006

(54) Method and storage device for testing A V-Chip

(75) Inventors: Miller Lee, Wugu Township (TW); Yih-Chau Lin, Wugu Township (TW)

Correspondence Address: BACON & THOMAS, PLLC, 625 SLATERS LANE, FOURTH FLOOR, ALEXANDRIA, VA, 22314, US

(73) Assignee: Hannspree, Inc., Taipei City (TW)

(21) Appl. No.: 11/257,193

(22) Filed: Oct. 25, 2005

(30) Foreign Application Priority Data
Jun. 10, 2005 (TW) 094119242

(51) Int. Cl. G01R 31/26

(52) U.S. Cl. 324/765

(57) ABSTRACT

A method and storage device for testing a V-Chip is disclosed. The storage device is operated with a reading device and a display device configured with the V-Chip. The storage device stores a plurality of testing frames and each of the testing frames includes a testing control signal. Thus, when the reading device reads one of the testing frames from the storage device and transmits the testing frame to the display device, the display device shows the testing frame if the testing frame does not belong to the media content which the V-Chip has been set to block. On the other hand, the display device shows a blocked message if the testing frame belongs to the media content which the V-Chip blocks.

### BACKGROUND OF THE INVENTION

1. Field of the Invention

The present invention relates to a testing method for a V-Chip and, more particularly, to a method and storage device for testing a V-Chip.

2. Description of Related Art

In the United States, a V-chip requirement was included in the Telecommunications Act, which was signed into law in February of 1996. The Act allows the parents to have the authority of selecting programs and makes the parents easily identify whether the program has violence or sexual content.

The Act requires television manufacturers to install the V-chips in all televisions and also asks the broadcasters to carry the rating information on the twenty-first scan line of each frame of the program. Hence, when one television receives a program, the V-Chip installed in the television determines whether to block the program or not in accordance with the rating information carried on the twenty-first scan line of each frame of the program. If the program has the media content that the V-Chip must block, the program is thus blocked and the television does not show the program. If the program does not contain the media content that the V-Chip must block, the television shows the program.

Accordingly, the televisions to be sold in the U.S. have to be installed with the V-Chips. However, the television manufacturers usually buy the V-Chips from the V-Chip vendors and then install the V-Chips to the televisions. Therefore, the television manufacturers have to test the V-Chips installed into the televisions to confirm the operation of the V-Chips before the televisions are sold.

Currently, the testing apparatuses for V-Chips are very expensive and occupy large space. If the testing apparatuses are applied to the mass production, it will increase the manufacturing cost and occupy large space. Furthermore, the television manufacturers may dispatch an FAE (Field Application Engineer) to the distributors or the customers to test whether the V-Chip works correctly or not, which results in a problem that the FAE cannot carry the huge testing apparatuses personally.

In addition, there are many films for different ratings in the markets. However, collecting these films having twenty-two ratings at the same time for testing the V-Chips is difficult.

Accordingly, a need exists for providing a testing apparatus which is inexpensive and does not occupy space.

### SUMMARY OF THE INVENTION

One object of the present invention is to provide a method and a storage device for testing a V-Chip so as to provide an inexpensive testing apparatus.

Another object of the present invention is to provide a method and a storage device for testing a V-Chip so as to provide a testing apparatus which does not occupy excessive space.

In accordance with one aspect of the invention, there is provided a storage device for testing a V-Chip. The storage device is operated with a reading device and a display device. The reading device is electrically connected to the display device including the V-Chip for blocking at least one media content. The storage device stores a plurality of testing frames, which are respectively corresponding to at least one rating. When the reading device reads one of the testing frames from the storage device and transmits the testing frame read by the reading device to the display device, the display device shows the testing frame if the testing frame does not belong to the media content which the V-Chip blocks.

In accordance with another aspect of the invention, there is provided a method for testing a V-Chip, which is applied to a storage device storing a plurality of testing frames respectively corresponding to at least one rating, and a reading device electrically connected to a display device, wherein the V-Chip is configured in the display device and is provided to block at least one media content, the method comprising the steps of: (A) reading one of the testing frames from the storage device through the reading device; (B) receiving the testing frame read by the reading device through the display device; and (C) comparing the testing frame read by the reading device with the media content blocked by the V-Chip through the V-Chip, wherein the display device shows the testing frame if the testing frame does not belong to the media content which the V-Chip blocks.

Other objects, advantages, and novel features of the invention will become more apparent from the following detailed description when taken in conjunction with the accompanying drawings.

### BRIEF DESCRIPTION OF THE DRAWINGS

The present invention, as defined in the claims, can be better understood with reference to the following drawings. The drawings are not necessarily to scale, emphasis instead being placed on clearly illustrating the principles of the present invention.

FIG. 1 is a block diagram in accordance with the preferred embodiment of the present invention;

FIG. 2 is a block diagram showing the manufacturing apparatuses for the storage device in accordance with the preferred embodiment of the present invention; and

FIG. 3 is a flowchart for testing the V-Chip in accordance with the preferred embodiment of the present invention.

### DETAILED DESCRIPTION OF THE PREFERRED EMBODIMENT

The present invention provides a storage device storing a plurality of testing frames, wherein the testing frames are used for testing the operation of the V-Chip. Therefore, the test of the V-Chip can be achieved by that a reading device reads one of the testing frames stored in the storage device and transmits the testing frame to a display device, and thereafter the V-Chip installed in the display device determines whether the testing frame belongs to the media content which the V-Chip blocks, thereby correctly testing the operation of the V-Chip.

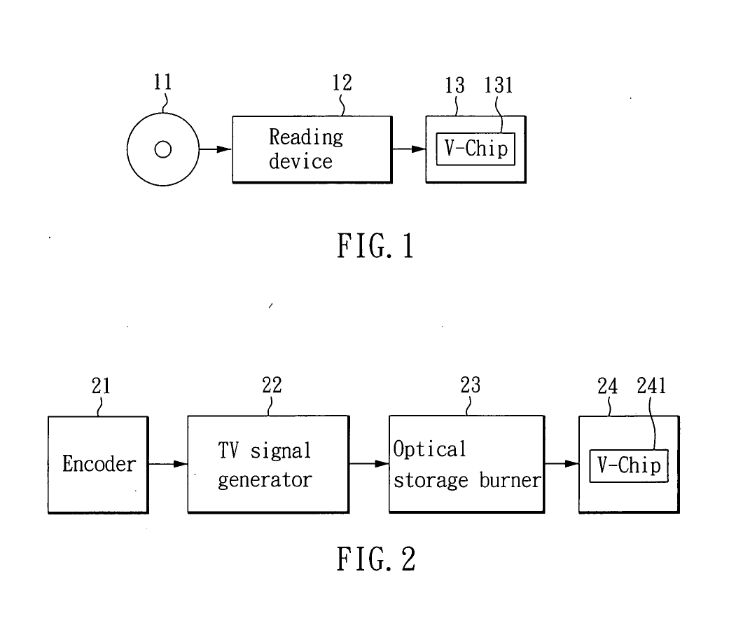

Reference will now be made in detail to the description of the invention as illustrated in the drawings with like numerals indicating like parts throughout the several views. With reference to FIG. 1, there is shown a block diagram according to the preferred embodiment of the present invention, which includes a storage device 11, a reading device 12 and a display device 13 including a V-Chip 131.

In this embodiment, the storage device 11 is an optical storage device. For example, the storage device 11 may be a VCD (Video Compact Disc), a DVD (Digital Video Disc), or the like. In this embodiment, the reading device 12 is an optical reading device, which may be a VCD player, a DVD player, or the like. In other embodiments, the storage device 11 may be a non-volatile storage device such as non-volatile memory. The reading device 12 may be an electrical device capable of reading data from the non-volatile storage device.

Furthermore, in this embodiment, the display device 13 is a flat panel display, such as a LCD TV or a PDP. In other embodiments, the display device 13 may be a traditional TV such as CRT TV, or the like.

The reading device 12 is electrically connected to the display device 13 so that the testing frame read by the reading device 12 can be transmitted to the display device 13.

The V-Chip 131 installed into the display device 13 can be provided to block at least one media content. According to the rules of the FCC (Federal Communication Commission), the program contents are classified into twenty-two media contents. The following table 1 shows the twenty-two media contents:

TABLE 1

| | | FV | V | S | L | D | |
|---|---|---|---|---|---|---|---|
| TV-Y | 1 | | | | | | |
| TV-Y7 | 2 | FV(3) | | | | | |
| TV-G | 4 | | | | | | |
| TV-PG | 5 | | V(6) | S(7) | L(8) | D(9) | V-S-L-D(10) |
| TV-14 | 11 | | V(12) | S(13) | L(14) | D(15) | V-S-L-D(16) |
| TV-MA | 17 | | V(18) | S(19) | L(20) | | V-S-L (21) |
| NR* | 22 | | | | | | |

The ratings include: TV-Y, TV-Y7, TV-G, TV-PG, TV-14, and TV-MA. TV-Y indicates that the program contains zero violence or sexual content, and is appropriate for all children including children from ages 2-6. TV-Y7 indicates that the program is most appropriate for children age 7 and above. Themes and elements in this program may include mild fantasy or comedic violence, or may frighten children under the age of 7. For those programs where fantasy violence may be more intense or more combative than other programs in this category, such programs will be designated TV-Y7-FV. TV-G indicates that the program is suitable for all ages, but is not necessarily a children's program and the program has no sex, violence or inappropriate language. TV-PG indicates that parental guidance is suggested, the program may not be suitable for younger children. This rating may also include a ‘V’ for violence, ‘S’ for sexual situations, ‘L’ for language, or ‘D’ for suggestive dialogue. TV-14 indicates that the program is for mature audiences only and may not be suitable for children under 14 (may be accompanied by V, S, L or D). TV-MA indicates that the program is suitable only for mature audiences and may contain graphic violence, explicit sexual activity or crude indecent language. When the film or movie producer provides programs, the rating information, such as rating code (FV), has to be carried on the twenty-first scan line of the frame of the program, causing the V-Chip 131 of the display device 13 to block the specific program in accordance with the setting in the V-Chip 131. Therefore, the present invention provides the storage device 11 storing twenty-two testing frames to test whether the V-Chip 131 is in a normal state. Alternatively, the storage device 11 may store one testing frame or several typical testing frames for reducing the testing time of the V-Chip 131.

FIG. 2 is a block diagram showing the manufacturing apparatus for the storage device 11, which includes an encoder 21, a TV signal generator 22, an optical storage burner 23 and a display device 24. The display device 24 is configured with a V-Chip 241.

The encoder 21 is electrically connected to the TV signal generator 22. The TV signal generator 22 is electrically connected to the optical storage burner 23. The optical storage burner 23 is electrically connected to the display device 24.

The encoder 21 provides a plurality of control signals, such as twenty-two different types of control signals. The TV signal generator 22 provides a TV signal and receives the control signal produced by the encoder 21, so that the TV signal generator 22 makes the TV signal carry the control signal to form a testing frame having a testing control signal. Thereafter, the TV signal generator 22 transmits the testing frame to the optical storage burner 23 including an optical storage medium, such as DVD-R, for burning.

The display device 24 is used for monitoring the production of the testing frame and receiving the testing frame from the optical storage burner 23 on the fly, thereby confirming whether the testing frame is available through the V-Chip 241 of the display device 24 immediately. If the testing frame is available, the testing frame is burned by the optical storage burner 23.

Therefore, the testing frames respectively including the testing control signals corresponding to different ratings can be stored in the storage device, such as a CD-R, to reduce the occupying space of the testing and provide a simple means for testing the V-Chip without using the conventional testing apparatuses which are very expensive and occupy large space. For example, the storage device provided by the present invention can be applied to the place, i.e., FAB or LAB, where the conventional testing apparatuses can not be placed. Besides, the storage device can be provided to the manufacturer, the out-sourcing bonding factory, the testing factory, the service shop and the sale persons for convenient use.

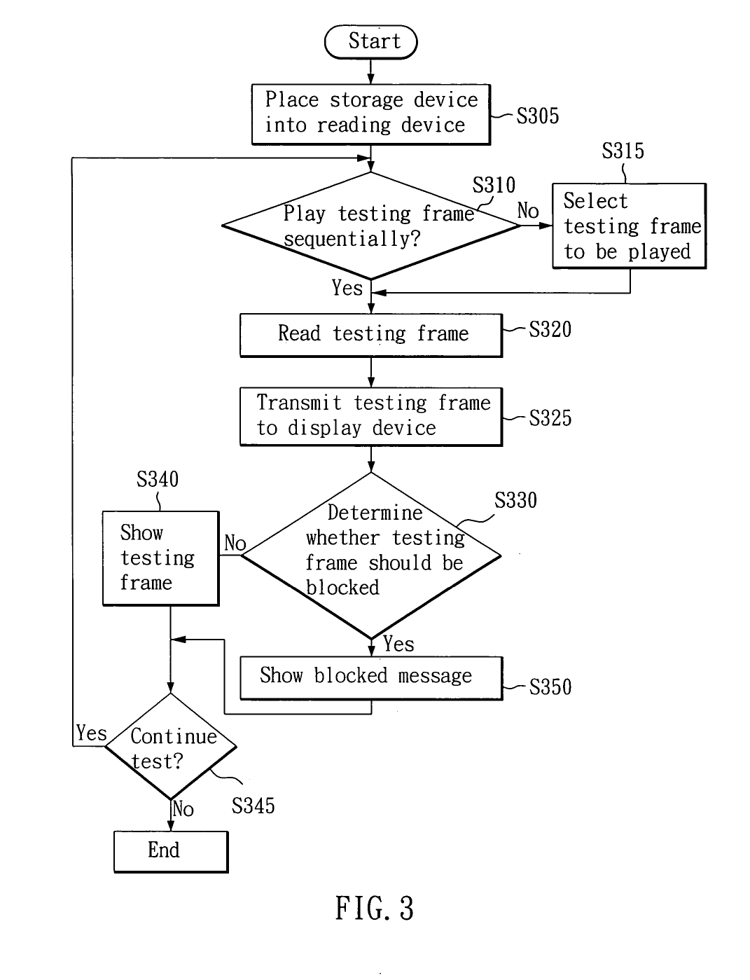

FIG. 3 is a flowchart for testing the V-Chip in accordance with the preferred embodiment of the present invention. Please refer to FIG. 3 as well as FIG. 1. First, the storage device 11, such as a DVD-R, is placed in the reading device 12 (S305). Since the storage device 11 is usually burned to be an auto-play format, the display device 13 shows a play menu, for example, a menu allowing twenty-two testing frames to be selected, after the storage device 11 is placed into the reading device. At this time, the user can select whether to play the testing frames sequentially (S310), or the user can non-sequentially select several typical testing frames to test the V-Chip 131 of the display device 13 (S315).

If the user selects to play the testing frames sequentially, the reading device 12 reads the testing frames from the first track of the storage device 12 (S320). Thereafter, the reading device 12 transmits the testing frame read by the reading device 12 to the display device 13 to test the V-Chip 131 (S325).

Next, the V-Chip 131 compares the testing frame and the media content that the V-Chip blocks to determine whether the testing frame belongs to the media content after the testing frame is transmitted to the display device 13 (S330). In this embodiment, the testing frame is a color bar having a plurality of colors or a frame having a single color. The time that the testing frame is played is 30seconds or several minutes. In other embodiments, the played time for the testing frame may be changed based on the demand of the user.

In this embodiment, the parent or the tester can set the V-Chip 131 through the OSD (On Screen Display) of the display device 13. In general, a password has to be entered through the OSD to prevent the children from setting the V-Chip 131. In this embodiment, the V-Chip 131 is set to block the media contents including TV-14-V rating and TV-14-S rating. In other embodiments, the tester may set the V-Chip 131 to block other media contents.

Therefore, the V-Chip 131 compares the testing control signal of the testing frame that the display device 13 receives with the media contents that have been preset to determine whether the testing frame should be blocked or not. If the testing frame belongs to the media content that the V-Chip 131 blocks, i.e., the testing frame belongs to the media content of the TV-14-V rating, the display device 13 shows a blocked message to indicate that the testing frame is blocked (S350). On the other hand, if the testing frame does not belong to the media content that the V-Chip 131 blocks, the display device 13 shows the testing frame (S340).

In general, the tester knows the media content blocked by the V-Chip 131 through operating the OSD. When the testing frame received by the display device 13 belongs to the specific media content that the V-Chip 131 has been set to block, the display device 13 still shows the testing frame, which indicates that the V-Chip 131 has failed. Thus, the tester can easily know whether the V-Chip 131 is in a normal state or not.

In many cases, the test for the V-Chip 131 needs to be performed several times for confirming the reliability of this test. Hence, if the tester selects to play the testing frame sequentially during testing the V-Chip 131, the reading device 12 continues to read the next testing frame when the testing frame has been tested. On the other hand, if the tester selects to play the testing frame non-sequentially, the tester needs to decide whether to continue to test (S345). If the tester decides to continue to test, then he/she may perform the step S310, otherwise the test for the V-Chip 131 is completed.

In view of the foregoing, it is known that the present invention provides a storage device storing a plurality of testing frames. Each of the testing frames includes a testing control signal. When the reading device reads one of the testing frames stored in the storage device, the reading device transmits the testing frame including the testing control signal to the display device, causing the V-Chip of the display device to determine whether the testing frame belongs to the media content that the V-Chip blocks based on the testing control signal of the testing frame. If the testing frame belongs to the media content, the V-Chip blocks the testing frame and the display device shows a blocked message. If the testing frame does not belong to the media content, the display device can show the testing frame. Therefore, it is able to provide a testing device which is inexpensive and does not occupy large space.

Although the present invention has been explained in relation to its preferred embodiment, it is to be understood that many other possible modifications and variations can be made without departing from the scope of the invention as hereinafter claimed.

What is claimed is:

1. A storage device for testing a V-Chip, which is applied to a reading device and a display device, the reading device being electrically connected to the display device having the V-Chip for blocking at least one media content, the storage device storing a plurality of testing frames respectively corresponding to at least one rating, wherein, when the reading device reads one of the testing frames from the storage device and transmits the testing frame to the display device, the display device shows the testing frame if the testing frame does not belong to the media content which the V-Chip has been preset to block.

2. The storage device as claimed in claim 1, wherein each of the testing frames further includes a testing control signal so that the V-Chip compares the testing control signal with the media content which the V-Chip is preset to block, thereby the display device showing a blocked message if the testing frame belongs to the media content.

3. The storage device as claimed in claim 1, wherein the V-Chip is detected to have failed when the testing frame belongs to the media content and the display device still shows the testing frame.

4. The storage device as claimed in claim 1, wherein the reading device sequentially reads one of the testing frames from the storage device and transmits the testing frame to the display device to test the V-Chip.

5. The storage device as claimed in claim 1, wherein the reading device non-sequentially reads one of the testing frames from the storage device and transmits the testing frame to the display device to test the V-Chip.

6. The storage device as claimed in claim 1, wherein the storage device stores twenty-two testing frames respectively corresponding to different ratings.

7. The storage device as claimed in claim 1, wherein the storage device is an optical storage device.

8. The storage device as claimed in claim 1, wherein the reading device is an optical reading device.

9. A testing method for a V-Chip, which is applied to a storage device storing a plurality of testing frames respectively corresponding to at least one rating, and a reading device electrically connected to a display device having the V-Chip for blocking at least one media content, the testing method comprising the steps of:
(A) reading one of the testing frames from the storage device through the reading device;
(B) receiving the testing frame read by the reading device through the display device; and
(C) comparing the testing frame with the media content blocked by the V-Chip through the V-Chip, wherein the display device shows the testing frame if the testing frame does not belong to the media content which the V-Chip has been preset to block.

10. The testing method as claimed in claim 9, wherein each of the testing frames further includes a testing control signal so that the V-Chip compares the testing control signal with the media content which the V-Chip is preset to block, thereby the display device shows a blocked message if the testing frame belongs to the media content.

11. The testing method as claimed in claim 9, wherein in the step (C), the V-Chip is detected to have failed when the testing frame belongs to the media content and the display device still shows the testing frame.

12. The testing method as claimed in claim 9, wherein in the step (A), the reading device sequentially reads one of the testing frames from the storage device and transmits the testing frame to the display device to test the V-Chip.

13. The testing method as claimed in claim 9, wherein in the step (A), the reading device non-sequentially reads one of the testing frames from the storage device and transmits the testing frame to the display device to test the V-Chip.

14. The testing method as claimed in claim 9, wherein the storage device is an optical storage device.

15. The testing method as claimed in claim 9, wherein the reading device is an optical reading device.

16. The testing method as claimed in claim 9, wherein the storage device stores twenty-two testing frames respectively corresponding to different ratings.
